(19) United States
(12) Patent Application Publication
(10) Pub. No.: US 2024/0183886 A1
(43) Pub. Date: Jun. 6, 2024

(54) ARRANGEMENT FOR EVALUATING THE STATE AND THE QUALITY OF LOW-VOLTAGE NETWORKS

(71) Applicant: DEHN SE, Neumarkt i.d.OPf. (DE)

(72) Inventors: Andreas Waigel, Neumarkt (DE); Hans Herold, Neumarkt (DE); Stefanie Schuster, Neumarkt (DE)

(21) Appl. No.: 17/798,711

(22) PCT Filed: Feb. 11, 2021
(86) PCT No.: PCT/EP2021/053366

§ 371 Date: Aug. 10, 2022

(30) Foreign Application Priority Data
Feb. 11, 2020 (DE) 10 2020 103 491.1

(51) Int. Cl. G01R 19/25; H02J 13/00

(52) U.S. Cl. CPC G01R 19/2513; H02J 13/00002; H02J 13/00022

(57) ABSTRACT

The invention relates to an arrangement for evaluating the condition and quality of low-voltage networks, in the branched system of which a multiplicity of connected consumers are located, by ongoing or cyclical determination of network measurement data by current and voltage analysis on the basis of power quality measuring and testing devices with transmission of the network measurement data by means of interfaces to a superordinate system or in retrievable form to a server or to the Cloud, wherein the measuring and testing devices are integrated in an assembly with external connections.

The invention relates to an arrangement for evaluating the condition and quality of low-voltage networks, in the branched system of which a multiplicity of connected consumers are located, by ongoing or cyclical determination of network measurement data by current and voltage analysis by means of power quality measuring and testing devices with transmission of the network measurement data by means of interfaces to a superordinate system or in retrievable form to a server or to the Cloud, wherein the measuring and testing devices are integrated in an assembly with external connections, according to the preamble of claim 1.

DE 10 2006 034 164 B4 discloses a multi-polar lightning current and/or over-voltage conductor of a terminal strip design. This over-voltage conductor preferably serves to protect information technology devices and systems and consists of a basic part designed as a through-terminal, and plug modules, which can be inserted into the base part, with protective elements for top hat rail mounting.

According to an embodiment thereof, a circuit board is provided which comprises a device for wireless sensing and condition monitoring e.g. in the form of an RFID transponder. The circuit board can also contain means for temperature monitoring of the protective elements located on the remaining circuit boards. Such means may be temperature sensors which are each located close to, in particular opposite, the protective elements.

In this respect, the known over-voltage conductor presented has a self-diagnostic unit.

The smart meter according to DE 20 2012 010 818 U1 comprises electronics to detect the power consumption and to output data representing the power consumption via a data communication interface.

In one variant, a LAN interface is provided for reading and programming the smart meter, while at least one further interface and the electronics of the smart meter are arranged to serve to control other external devices which can then be controlled e.g. via a field bus system by the smart meter also connected to the field bus system.

The possibility also exists of integrating a web server into the housing of the smart meter so that the power consumption determined by the smart meter can be retrieved by external devices, e.g. including by mobile telephones, via the internet with the aid of suitable software.

WO 2016/091239 A1 discloses a measuring and/or testing apparatus and a method for measuring and/or estimating the quality or stability of power networks.

This document elaborates that, by reason of novel distributed generator units for the provision of electrical energy, system incidents arise in many cases owing to a lack of measuring devices for detection of the voltage quality. A network supplied in a decentralised manner requires a minimum level of likewise decentralised measuring and regulating devices in order to be able to operate the network in a stable and efficient manner, and in order to detect and remedy problems in the power quality in end consumer households. In relation to this, the known solution proposes a measuring and/or testing apparatus which is designed with network tapping means and a power pack, which is equipped with a unit with at least one AD converter circuit for continuous sensing, digitising and reproduction of at least voltage and/or frequency values of the mains voltage via an interface. A microcontroller unit serves to provide and/or convert the data and is connected to the measuring and/or testing apparatus.

The method includes determination of network measurement data, reproduction of the measurement data via a first local data connection of an internal microcontroller unit or an IT device, processing and/or handling, but also evaluation of the data in the microcontroller unit and/or the IT device and provision of a timestamp and location to the data. The data are subsequently transmitted via a second data connection to a computing centre and/or a further IT device and/or a storage medium. In the computing centre or the power supplier, the data can then be evaluated and intervention into the network can be effected if necessary.

EP 2 478 607 B1 also proposes a method for monitoring an electric power supply network, in which, at at least two different measuring points in the power supply network, a detection of measurement data which characterises the condition of the electrical power supply network is carried out.

DE 10 2013 018 482 A1 discloses a method and an apparatus for automatically characterising and monitoring an electrical network or a section of a power network of an electrical network or electrical system. The aim of the teaching therein is to be able make decisions for the avoidance of breakdowns even in advance of the event and/or to carry out necessary switching procedures or other countermeasures automatically. Furthermore, network quality measuring devices are known which are also designed for top hat rail mounting. For example, in this case reference is made to the device UMD 705 of the company Helvatron (see www.helvatron.com/de/power-quality/umd-705).

From DE 10 2018 114 181 A1, a method for evaluating the condition and quality of low-voltage networks is previously known. According to this method, over-voltage protective devices, which are inserted in low-voltage systems and are already provided or insertable and have a self-diagnostic unit and a wireless or wired standard interface, are trained to determine network measurement data by means of integrated or adapted power quality measuring and testing devices.

With training of these over-voltage protective devices, which are provided or can be inserted, for determination of network measurement data, a new quality of penetration or permeation of the network exists so that not only can the network quality be assessed but there is also the possibility of adapting the level of protection of the over-voltage protective devices, e.g. in the case of switching procedures in the network. According to DE 10 2018 114 181 A1, over-voltage protective devices can already be provided with a power quality measuring and testing device. The function for network quality determination, which is integrated in the over-voltage conductor, can then be enabled or retrieved manually or via a data command.

The advantage of function integration is that it is not necessary per se to install separate devices and to create an additional communication channel.

However, precisely this latter aspect also leads to the situation where, during replacement of the actual over-voltage protective device e.g. owing to the activation of an inserted conductor, the whole unit must be changed, which ultimately leads to higher costs and effort for the operator.

On the basis of the foregoing, it is the object of the invention to provide a further-developed arrangement for evaluating the condition and the quality of low-voltage networks, in the branched system of which a multiplicity of connected consumers are located, which on the one hand are easily inserted or integrated into existing or control cabinets, service switch cabinets or the like to be set up, and wherein a simple possibility is provided for wiring, i.e. incorporation into the network in addition to a power supply.

Furthermore, the arrangement to be provided should create diverse possibilities for how it is operated, including in terms of client-specific external programming, with the aim of controlling e.g. switching procedures of connected consumers in order ultimately to increase the operating safety of a consumer-end network.

The object of the invention is achieved according to the combination of features of claim 1, wherein the dependent claims constitute at least expedient embodiments and developments.

An arrangement for evaluating the condition and the quality of low-voltage networks is accordingly assumed, in the branched system of which a multiplicity of connected consumers is, or can be, located. In this case, the corresponding condition of the network is examined by ongoing or cyclical determination of network measurement data by current and voltage analysis by the use of power quality measuring and testing devices. Furthermore, there is a transmission of the network measurement data by means of interfaces to a superordinate system or in retrievable form to a server or to the Cloud.

The measuring and testing devices for the power quality measurements are integrated in an assembly with external connections.

This assembly can be located in a housing which has comparable dimensions to in particular a multi-polar over-voltage conductor. This is an advantage if a neighbouring quasi-series arrangement is provided on a top hat rail or similar fastening means.

In this respect, the assembly comprises a housing comprising means for fastening on a top hat rail or similar standard mounting device.

Furthermore, on one of the housing side surfaces, a combination of terminals for single-wire or multi-wire connection and for receiving contact strips of a standard comb rail is formed.

This design is implemented in that, by means of a neighbouring electronic component on the respective top hat rail, voltage is supplied by means of a comb rail and/or the terminals can be inserted in relation thereto.

Both the terminals and also the connections for receiving the standard comb rail permit looping-through or electrical relaying to further electronic or electrotechnical components which are located in the respective vicinity.

Thus it is possible e.g. for neighbouring allocation of the assembly in accordance with the invention to a conventional multi-polar over-voltage conductor. Thus the multi-polar over-voltage conductor is preferably located on said top hat rail. The assembly is accordingly fixed close by. By means of a standard comb rail structured in relation to this, a desired voltage supply and also data transmission between the assembly and over-voltage conductor arrangement can then be effected.

If, on the one hand, the standard comb rails are used for power supply to the assembly, then—as stated—the possibility exists of looping-through or relaying to further electronic components via the available now-free terminals which are located or disposed on the housing side surface in question.

The electronic component in question can thus be in particular a multi-polar over-voltage conductor arrangement which is located in a housing suitable for top hat rail mounting.

The housing contours of both the electronic component and also of the assembly are preferably complementarily adapted to each other in terms of a series arrangement which is also visually continuous.

In terms of structure, the possibility exists of designing the assembly in a different colour to the housing of the over-voltage conductors by reason of its special functions.

In a development, the respective comb rail has integrated sensors in its bridge section for connection of the contact strips.

These integrated sensors can serve for detection of electrical and/or environmental parameters.

In such an embodiment of the invention, otherwise necessary additional wiring is omitted owing to the use of sensors which may be necessary.

By means of the comb rail connection, data relating to the operating condition of the correspondingly neighbouring electronic component can additionally also be transmitted to the assembly.

However, such data transmission can also take place bidirectionally, i.e. from the assembly to the electronic component, in order to influence this component e.g. with respect to its parameters, in particular to carry out parameter changes.

From the respectively neighbouring electronic component, there is a wireless transmission of condition data and operating parameters to the assembly when e.g. an activation or enabling code is detected owing to the approach or installation of the assembly in relation to the electronic component or vice versa.

The activation or enabling code can be triggered by a switching device which is based on a positive or non-positive connection between the assembly and the component.

Alternatively such an activation or enabling code can be triggered with a signal which is based on information to be transmitted wirelessly in the near field.

If both the assembly and also the electronic component are provided with detection parameters, self-calibration can be effected when the component and assembly necessarily come closer together e.g. by installation on a top hat rail in an appropriate service switch cabinet. The wireless data transmission for detecting a component on the one hand and an assembly on the other hand can be implemented inductively but in particular also with the aid of an RFID tag.

The proposed positive and/or non-positive connection can be implemented by encoded plug elements which correspond to associated apertures in the neighbouring device, wherein it is possible to resort to a switching device directly or even indirectly e.g. owing to magnetic forces in association with a reed relay.

On a further one of the housing side surfaces, the assembly comprises a multiplicity of connections for external sensors and/or for an external power supply which is independent of the network to be examined.

In one embodiment, the external sensors can comprise a plurality of phase-related Rogowski coils which are designed in an appropriate contained arrangement and provided with means to fix same to the conductor or busbar in question.

Said external power supply is effected in such a way that no current is drawn at the measurement point itself and is thus also suitable for use in the area of pre-meters. If the corresponding external supply is fail-safe with respect to the measurement signal, detection of breaks and interruptions in the network can be effected according to normative requirements. This means that there are thus no limitations and complete detection according to standards can be achieved.

In one embodiment of the invention, the assembly comprises at least one integrated air interface.

This air interface can be produced as an integrated 2.4 GHz radio module with an integrated antenna for WLAN or Cloud connection or as a Bluetooth interface for parametrisation using application software.

According to one operating unit, which is also a component of the assembly, parametrisation, calibration and/or switching of input and/or output ports can be initiated.

Signal processing is carried out by means of said sensors and a microcontroller integrated in the assembly, in such a way that pulsed current detection, load current detection and/or monitoring of network-frequency over-voltage are made possible.

Information can be transmitted to the assembly via one of its inputs or interfaces, the information being provided via Cloud services e.g. in the form of weather warnings, in order to trigger network-relevant or consumer-relevant switching procedures, to output warnings or the like.

With the aid of the ports or interfaces, it is possible to calibrate or parametrise the respective over-voltage conductor, which is preferably close by. In terms of the detection of the properties of the neighbouring part as presented, this can be carried out automatically but also on the basis of a command to be triggered.

The invention will be explained in more detail hereinunder with the aid of exemplified embodiments and with reference to figures.

In the drawing:

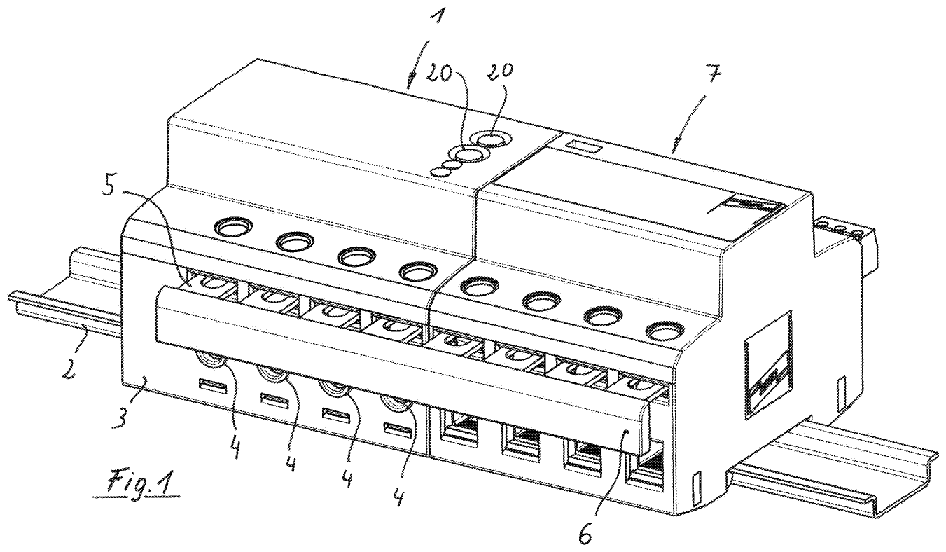

FIG. 1 shows a perspective view of the assembly in accordance with the invention in the immediate proximity of a multi-polar over-voltage conductor mounted on an indicated top hat rail, seen looking towards a first one of the housing side surfaces with a combination of terminals at that location for single-wire or multi-wire connection and for reception of contact strips of a standard comb rail. In FIG. 1, the standard comb rail has not yet been fully pushed into the associated connection sections;

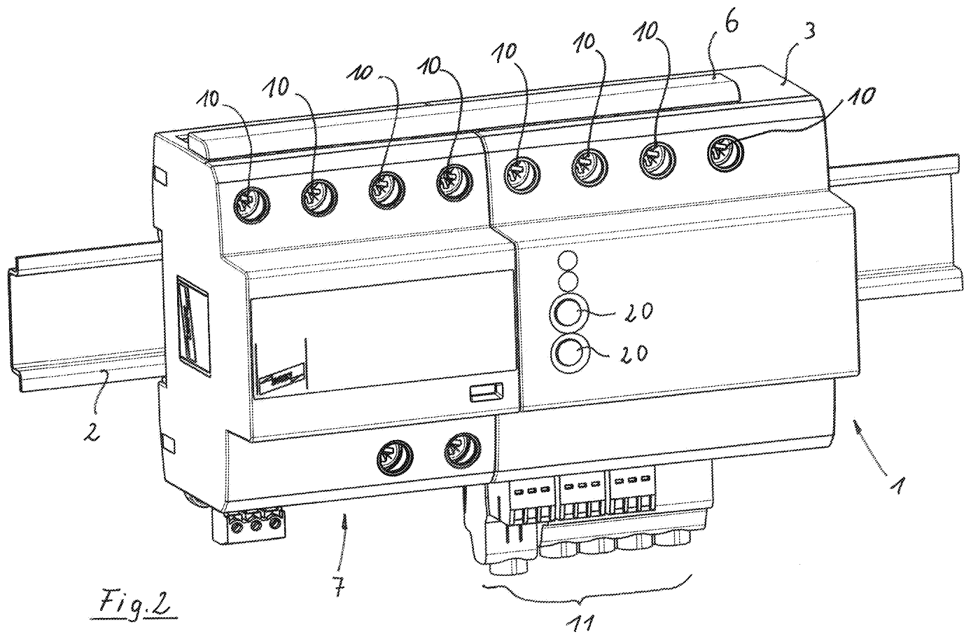

FIG. 2 shows a view similar to that of FIG. 1 but with the comb rail fully pushed in and a view of a multiplicity of connections, located on a further housing side surface, for external sensors or even for the feeding-in of a network-independent power supply;

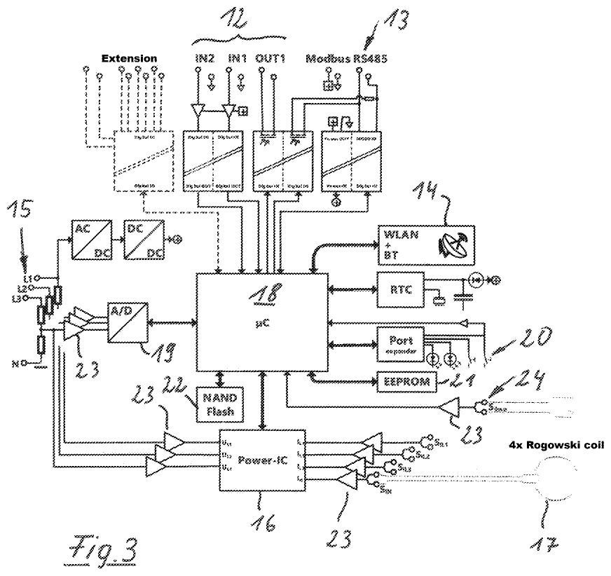

FIG. 3 shows a circuit diagram of the assembly in accordance with the invention; and

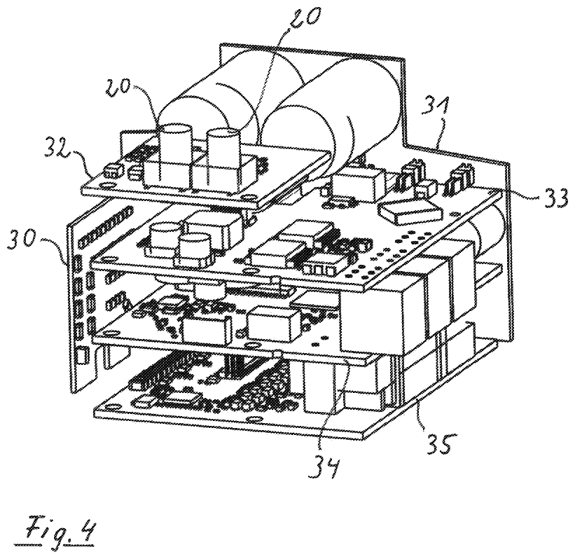

FIG. 4 shows a view of the circuit board module located in the housing (see FIGS. 1 and 2) which shows that the whole housing, which is virtually top hat shaped in cross-section, is optimally used in terms of the available installation space.

According to the views of FIGS. 1 and 2, an assembly 1 in accordance with the invention is assumed, which comprises a housing which has means for fastening to a top hat rail 2 and an identical standard mounting device.

On the housing side surface 3, which is in the foreground in FIG. 1, a combination of terminals 4 for single-wire or multi-wire connection and for receiving contact strips 5 of a standard comb rail 6 is formed.

It is thus possible, on the one hand, via a neighbouring electronic component disposed on the respective top hat rail 2, e.g. in the form of a multi-polar over-voltage conductor 7, to effect a voltage supply by means of a comb rail 6 and/or to use the terminals 4 in relation thereto.

Both the terminals and also the connections for receiving the standard comb rails permit looping-through or electrical relaying to further electronic components.

In the view of FIG. 2, the comb rail 6 is pushed fully into the associated receivers for the contact strips 5 both in the over-voltage protective device 7 and also in the assembly 1. A secure mechanical and electrical contact is produced by tightening the screw connections 10.

The comb rail connecting bridge can have sensors (not shown in the figures) on its inside for detection of electrical and/or environmental parameters.

On a further one of the housing side surfaces, the assembly 1 has a multiplicity of connections for external sensors and/or for an external power supply which is independent of the network to be examined. Said means are shown collectively by the reference sign 11 in FIG. 2.

As can be understood with the aid of the circuit diagram of FIG. 3, the assembly has a group of input and output ports 12 and a further parametrisable interface 13. A combined 2.4 GHz radio module with an integrated antenna permits WLAN or Cloud connection but also parametrisation via an app or over a Bluetooth connection. The module is shown by the reference sign 14 in the circuit diagram.

In the case of a first possibility for the power supply to the assembly, this can be effected via three voltage dividers 15 and connection of L1 to the power conductor board. Alternatively, however, a separate power supply can also be provided.

An AC/DC converter converts the mains voltage at L1 to the required direct voltage, e.g. 24 volts and includes outage bridging. A power circuit 16 has a preset number of connections for current sensors, e.g. designed as Rogowski coils 17. Said modules correspond with a microcontroller 18, the digital inputs of which have AD converters 19 connected upstream of them where necessary.

Display and operation take place via an exemplified key combination in conjunction with light-emitting diodes 20. By means of EEPROM 21 it is possible to store parameters. Furthermore, a NAND flash 22 serves as a measurement data memory.

The necessary signal adaptation is effected via appropriate amplifiers 23.

An input 24 is designed as a pulse measuring input 100 kA at 100 A resolution with a 1 MHz sensing rate.

The power circuit 16 serves to determine current, power and energy based on the measurement signals provided by the Rogowski coils 17 via the amplifiers 23.

Said assembly thus constitutes an intelligent measurement system for monitoring low-voltage quality parameters and for monitoring over-voltage protective devices and for incorporating further sensors and actuators. The system is able to correspond with the Cloud, i.e. to transfer or store data therein.

Owing to the fact that the provided inputs and outputs are freely programmable, switching procedures can take place which are triggered either by the assembly itself or an occurring event. Remote triggering via a communication path can likewise take place.

If, for instance, an event occurs, e.g. in the form of the voltage falling below the mains voltage or the Cloud signalling that bad weather is approaching the installation site, either the switching outputs are acted upon directly or there is a logical programmable linking in order to deduce a new event from the result of the linking, that now switches a relevant output or triggers a warning or the like.

It is likewise possible to monitor the connected neighbouring over-voltage conductor. In relation to this, on the one hand, a telecommunications contact of the over-voltage conductor, which is provided as a matter of course, can be interrogated. Furthermore, it is possible to check the earth leakage path of the over-voltage conductor continuously via the pulsed current measurement. It is therefore possible to detect the condition of the neighbouring SPD prior to triggering the telecommunications contact and to initiate measures if applicable.

Furthermore, it is possible to incorporate external signal sources into the signal processing and to be able to work via the bidirectional communication between device and Cloud from both sides to both sides or in both directions.

The view of FIG. 4 shows an exemplified advantageous structure of an arrangement consisting of a plurality of quasi-nested circuit boards as wiring carriers. The circuit board 30 is in this case designed as a circuit board for connection to L1 via appropriate contacting.

The circuit board 31 generates the necessary direct voltage for device supply from the signal L1, wherein, for supply purposes, it is also possible to connect from a secured external direct current source.

The circuit board 32, which is preferably orientated towards the upper side of the housing of the assembly, accommodates keys as operating elements, light-emitting diodes as display elements and a radio module for device operation, parametrisation and Cloud connection.

A further circuit board 33 located thereunder comprises the electronics supply and galvanically separated wire-guided interfaces, a clock with quartz and further components. The sandwiched circuit board 34 accommodates the microcontroller with external and integrated AD converters, memory input and pulsed current measurement input.

The basic circuit board 35 comprises the power circuit in addition to input switching wiring for the sensors, in particular the Rogowski coils including terminal units.

The arrangement and selection of the mounting and the design of the circuit boards are effected such that the necessary electromagnetic compatibility is ensured and it is possible to prevent corruption of the measurement results by pulsed currents or other disturbances.

1. Arrangement for evaluating the condition and quality of low-voltage networks, in the branched system of which a multiplicity of connected consumers are located, by ongoing or cyclical determination of network measurement data by current and voltage analysis by means of power quality measuring and testing devices with transmission of the network measurement data by means of interfaces to a superordinate system or in retrievable form to a server or to the Cloud, wherein the measuring and testing devices are integrated in an assembly with external connections,
characterised in that
the assembly (1) comprises a housing comprising means for fastening on a top hat rail (2) or similar standard mounting device, wherein, on one of the housing side surfaces (3), a combination of terminals (4) for single-wire or multi-wire connection and for receiving contact strips (5) of a standard terminal rail (6) is formed in such a way that, on the one hand, by means of a neighbouring electronic component (7) on the respective top hat rail (2), voltage is supplied by means of a comb rail (6) and/or the terminals (4) can be inserted in relation thereto, wherein both the terminals (4) and also the connections for receiving the standard comb rail (6) permit looping-through or electrical relaying to further electronic components.

2. Arrangement as claimed in claim 1,
characterised in that
the at least one electronic component is designed as a top hat rail-mountable over-voltage conductor (7).

3. Arrangement as claimed in claim 1,
characterised in that
for connection of the contact strips (5), the comb rail (6) in its bridge section has integrated sensors for detection of electrical and/or environmental parameters.

4. Arrangement as claimed in claim 1,
characterised in that
by means of the comb rail connection, data relating to the operating condition of the neighbouring electronic component, in particular of the over-voltage conductor, can additionally be transmitted.

5. Arrangement as claimed in claim 4,
characterised in that
the data can be transmitted bidirectionally.

6. Arrangement as claimed in claim 1,
characterised in that
from the respectively neighbouring electronic component (7), there is a wireless transmission of condition data and operating parameters to the assembly when an activation or enabling code is detected owing to the approach or installation of the assembly (1) in relation to the electronic component (7) or vice versa.

7. Arrangement as claimed in claim 6,
characterised in that
the activation or enabling code can be triggered by a switching device which is based on a positive or non-positive connection between the assembly (1) and the component (7).

8. Arrangement as claimed in claim 6,
characterised in that
the activation or enabling code can be triggered by a switching device which is based on information transmitted wirelessly in the near field.

9. Arrangement as claimed in claim 1,
characterised in that
on a further one of the housing side surfaces, the assembly (1) comprises a multiplicity of connections (11) for external sensors and/or for an external power supply which is independent of the network to be examined.

10. Arrangement as claimed in claim 1,
characterised in that
the assembly (1) has at least one integrated air interface (14).

11. Arrangement as claimed in claim 1,
characterised in that
by means of an operating unit (20), which is a component of the assembly (1), parametrisation, calibration and/or switching of ports can be initiated.

12. Arrangement as claimed in claim 9,
characterised in that
pulsed current detection, load current measurement and/or monitoring of network-frequency over-voltages are carried out by means of the sensors and a microcontroller (18) integrated in the assembly.

13. Arrangement as claimed in claim 1,
characterised in that
information can be transmitted to the assembly (1) via one of its inputs or interfaces, the information being provided via Cloud services e.g. in the form of weather warnings, in order to trigger network-relevant or consumer-relevant switching procedures.

14. Arrangement as claimed in claim 2,
characterised in that
the over-voltage conductor (7), which is preferably close by, can be calibrated or parametrised using the provided information.
